(19) United States
(12) Patent Application Publication
(10) Pub. No.: US 2010/0112438 A1
(43) Pub. Date: May 6, 2010

(54) ENERGY CELL PACKAGE

(75) Inventor: Chien-Chiang CHAN, TAIPEI HSIEN (TW)

Correspondence Address: BRIAN M. MCINNIS, 12th Floor, Ruttonjee House, 11 Duddell Street, Hong Kong, HK

(73) Assignee: Chien-Chiang CHAN, TAIPEI HSIEN (TW)

(21) Appl. No.: 12/328,775

(22) Filed: Dec. 5, 2008

(30) Foreign Application Priority Data
Nov. 6, 2008 (TW) 97142938

(51) Int. Cl. H01M 2/20; H05K 7/02

(52) U.S. Cl. 429/211; 361/809

(57) ABSTRACT

An energy cell package includes an energy cell, a first metal substrate, a second metal substrate, at least one first jointing component, at least one second jointing component, and an insulating structure. The energy cell has at least one positive contact and at least one negative contact. The first metal substrate has an end functioning as an external positive contact. The second metal substrate has an end functioning as an external negative contact. The at least one first jointing component joints the at least one positive contact and the first metal substrate, and the at least one second jointing component joints the at least one negative contact and the second metal substrate. Except the external positive contact and external negative contact, the insulating structure coats the energy cell, first metal substrate, second metal substrate, at least one first jointing component, and at least one second jointing component.

### RELATED APPLICATIONS

This application claims priority to Taiwan Application Serial Number 97142938, filed Nov. 6, 2008, which is herein incorporated by reference.

### BACKGROUND

1. Field of Invention

The present invention relates to a cell package. More particularly, the present invention relates to an energy cell package.

2. Description of Related Art

Energy storage parts play important roles in our daily lives since they influence the performance and the working time of electronic devices. Components such as capacitors used in the circuits and batteries used in portable devices are the most common energy storage parts.

In the past, the solution to backup power source is mainly lead-acid batteries. Nowadays, there are more choices available to meet the demand for backup power source, such as lithium-ion batteries, nickel-hydrogen batteries, fuel cells, solar cells, and Electric Double-Layer Capacitors.

Lithium-ion batteries, nickel-hydrogen batteries, and other battery technologies are reliable power storage solutions, and they are already applied in many designs and solved many cost-related problems. However, they still possess the same problem as lead-acid batteries. Since they are based on chemical reactions, their life is limited and influenced by the temperature and current. So, in terms of durability and reliability issues, the above mentioned battery technologies pose some challenges.

Ultra-capacitors, also called Electric Double-Layer Capacitors (EDLC), have substantially high power density. In the past few years, these components have been used in consumer electronics, industrial and automotive applications. Today, ultra-capacitors with 20 kW/kg of power densities are already available, and they have very compact sizes (a small ultra-capacitor usually has a stamp size or even smaller). They can store a lot more energy than traditional capacitors. Faraday (F) is the unit of the capacitance value used by most ultra-capacitors, usually in 1 F to 5000 F. The discharge rate can be very quick and can also be very slow. Their life is very long and can be designed for the entire life cycle of end products.

High efficiency energy cells such as ultra-capacitors and magnetic capacitors will be applied in many areas in the near future. So, a package structure for the energy cells has its demand.

### SUMMARY

According to one embodiment of the present invention, an energy cell package includes an energy cell, a first substrate, first jointing components, second jointing components, and an insulating structure. The substrate has a first conductive wire and a second conductive wire thereon. The energy cell has positive contacts and negative contacts. The first jointing components are used to joint positive contacts and the first conductive wire. The second jointing components are used to joint the negative contacts and the second conductive wire. Except the part on the substrate that is plated with metal, the insulating structure coats the substrate, the energy cell, the first jointing components, and the second jointing components.

According to another embodiment of the present invention, an energy cell package includes an energy cell, a first metal substrate, a second metal substrate, first jointing components, second jointing components, and an insulating structure. The first metal substrate has an end outside the insulating structure as an external positive contact. The second metal substrate has an end outside the insulating structure as an external negative contact. The energy cell has a positive contact and a negative contact. The first jointing components are used to joint the positive contacts and the first metal substrate. The second jointing components are used to joint the negative contacts and the second metal substrate. Except the external positive contact and the external negative contact, the insulating structure coats the energy cell, the first metal substrate, the second metal substrate, the first jointing components, and the second jointing component.

### BRIEF DESCRIPTION OF THE DRAWINGS

The accompanying drawings are included to provide a further understanding of the invention, and are incorporated in and constitute a part of 20 this specification. The drawings illustrate embodiments of the invention and, together with the description, serve to explain the principles of the invention. In the drawings,

FIG. 1 is a side view of an energy cell package according to a first embodiment of the invention; and

FIG. 2 is a side view of an energy cell package according to a second embodiment of the invention.

### DESCRIPTION OF THE PREFERRED EMBODIMENTS

Reference will now be made in detail to the embodiment of this invention, examples of which are illustrated in the accompanying drawings. Wherever possible, the same reference numbers are used in the drawings and the description to refer to the same or like parts.

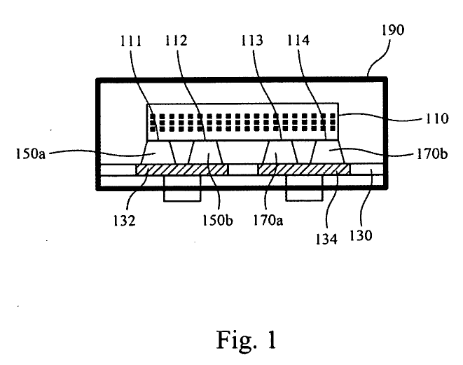

The energy cells in the following embodiments are high efficiency energy cells such as super capacitors, magnetic capacitors, and miniature flat type batteries. In addition, the embodiments described below take energy cells having two positive contacts and two negative contacts for illustrative example. In other embodiments, the number of positive and negative contacts of a single energy cell can be one or more than two so as to provide various applications for different industries. FIG. 1 is a side view of an energy cell package according to a first embodiment of the invention. The energy cell package includes an energy cell 110, a first substrate 130, first jointing components 150a and 150b, second jointing components 170a and 170b, and an insulating structure 190.

The substrate 130 has a first conductive wire 132 and a second conductive wire 134 thereon. The energy cell 110 has positive contacts 111 and 112 and negative contacts 113 and 114. The first jointing components 150a and 150b are used to joint positive contacts 111, 112 and the first conductive wire 132. The second jointing components 170a and 170b are used to joint the negative contacts 113, 114 and the second conductive wire 134. Except the part on the substrate 130 that is plated with metal (so as to be an external positive contact and an external negative contact), the insulating structure 190 coats the substrate 130, the energy cell 110, the first jointing components 150a and 150b, and the second jointing components 170a and 170b. The insulating structure 190 may be made of Epoxy resin, ceramic or glass.

The external positive contact and the external negative contact of the energy cell package may be placed on the same side, the neighboring sides, or the opposite sides according to the actual demand. In this embodiment, the external positive contact and the external negative contact are set on the same side of the energy cell package. The width of the first conductive wire 132 on the substrate 130 is greater than the width of the first jointing component 150a and 150b, and the width of the second conductive wire 134 is greater than the width of the second jointing component 170a and 170b. The material of the first jointing components 150a and 150b and the second jointing components 170a and 170b may be gold, copper, aluminum, silver, tin, combination alloy from the above metal, or other conductive material. The first jointing components 150a and 150b and the second jointing components 170a and 170b may be metal bumps, metal bonding wires, solder or other conductive material so as to achieve the goal of jointing and electrical conduction.

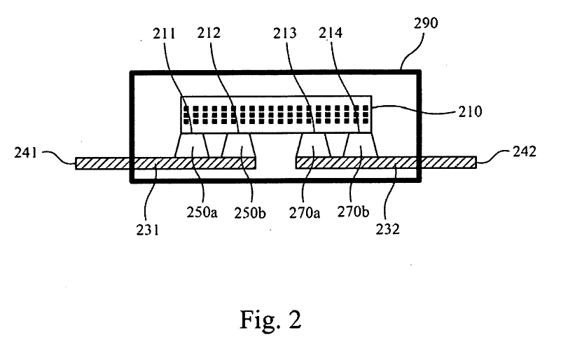

FIG. 2 is a side view of an energy cell package according to a second embodiment of the invention. The energy cell package includes an energy cell 210, a first metal substrate 231, a second metal substrate 232, first jointing components 250a and 250b, second jointing components 270a and 270b, and an insulating structure 290.

The first metal substrate 231 has an end outside the insulating structure as an external positive contact 241. The second metal substrate 232 has an end outside the insulating structure as an external negative contact 242. The energy cell 210 has a positive contact 211 and a negative contact 214. The first jointing components 250a and 250b are used to joint the positive contacts 211, 212 and the first metal substrate 231. The second jointing components 270a and 270b are used to joint the negative contacts 213, 214 and the second metal substrate 232. Except the external positive contact 241 and the external negative contact 242, the insulating structure 290 coats the energy cell 210, the first metal substrate 231, the second metal substrate 232, the first jointing components 250a and 250b, and the second jointing component 270a and 270b. The insulating structure 290 may be made of Epoxy resin, ceramic or glass.

The external positive contact 241 and the external negative contact 242 of the energy cell package may be placed on the same side, the neighboring sides, or the opposite sides according to the actual demand. In this embodiment, the external positive contact 241 and the external negative contact 242 are set on the opposite sides of the energy cell package. The width of the first first metal substrate 231 is greater than the width of the first jointing component 250a and 250b, and the width of the second metal substrate 232 is greater than the width of the second jointing component 270a and 270b. The material of the first jointing components 250a and 250b and the second jointing components 270a and 270b may be gold, copper, aluminum, silver, tin, combination alloy from the above metal, or other conductive material. The first jointing components 250a and 250b and the second jointing components 270a and 270b may be metal bumps, metal bonding wires, solder or other conductive material so as to achieve the goal of jointing and electrical conduction.

As a further application, the parallel connections of different numbers of the positive contacts on the energy cell may be achieved by connecting the jointing components to the substrate first and then forming parallel connections on the substrate with appropriate means, and the same is for the negative contacts.

It will be apparent to those skilled in the art that various modifications and variations can be made to the structure of the embodiment without departing from the scope or spirit of the invention. In view of the foregoing, it is intended that the embodiment cover modifications and variations of this invention provided they fall within the scope of the following claims and their equivalents.

What is claimed is:

1. An energy cell package comprising:
an energy cell having at least one positive contact and at least one negative contact;
a substrate having a first conductive wire and a second conductive wire thereon;
at least one first jointing component for jointing the at least one positive contact and the first conductive wire;
at least one second jointing component for jointing the at least one negative contact and the second conductive wire; and
an insulating structure coating the energy cell, the substrate, the at least one first jointing component, and the at least one second jointing component.

2. The energy cell package of claim 1, wherein the energy cell is a battery or a capacitor.

3. The energy cell package of claim 1, wherein the substrate is plated with metal so as to be an external positive contact and an external negative contact.

4. The energy cell package of claim 3, wherein the external positive contact and the external negative contact are placed on the same side, the neighboring sides, or the opposite sides.

5. The energy cell package of claim 1, wherein the width of the first conductive wire is greater than the width of the at least one first jointing component, and the width of the second conductive wire is greater than the width of the at least one second jointing component.

6. The energy cell package of claim 1, wherein the material of the insulating structure is Epoxy resin, ceramic or glass.

7. The energy cell package of claim 1, wherein the material of the at least one first and second jointing component is gold, copper, aluminum, silver, tin, combination alloy from the above metal, or other conductive material.

8. The energy cell package of claim 7, wherein the at least one first jointing component and the at least one second jointing component are metal bumps.

9. The energy cell package of claim 7, wherein the at least one first jointing component and the at least one second jointing component are metal bonding wires.

10. The energy cell package of claim 7, wherein the at least one first jointing component and the at least one second jointing component are solder or other conductive material.

11. An energy cell package comprising:
an energy cell having at least one positive contact and at least one negative contact;
a first metal substrate having an end as an external positive contact;
a second metal substrate having an end as an external negative contact;
at least one first jointing component for jointing the at least one positive contact and the first metal substrate;
at least one second jointing component for jointing the at least one negative contact and the second metal substrate; and
an insulating structure coating the energy cell, the first metal substrate, the second metal substrate, the at least one first jointing component, and the at least one second jointing component except the external positive contact and the external negative contact.

12. The energy cell package of claim 11, wherein the energy cell is a battery or a capacitor.

13. The energy cell package of claim 11, wherein the external positive contact and the external negative contact are placed on the same side, the neighboring sides, or the opposite sides.

14. The energy cell package of claim 11, wherein the width of the first metal substrate is greater than the width of the at least one first jointing component, and the width of the second metal substrate is greater than the width of the at least one second jointing component.

15. The energy cell package of claim 11, wherein the material of the insulating structure is Epoxy resin, ceramic or glass.

16. The energy cell package of claim 11, wherein the material of the at least one first and second jointing component is gold, copper, aluminum, silver, tin, combination alloy from the above metal, or other conductive material.

17. The energy cell package of claim 16, wherein the at least one first jointing component and the at least one second jointing component are metal bumps.

18. The energy cell package of claim 16, wherein the at least one first jointing component and the at least one second jointing component are metal bonding wires.

19. The energy cell package of claim 16, wherein the at least one first jointing component and the at least one second jointing component are solder or other conductive material.
